(19) United States
(12) Patent Application Publication
(10) Pub. No.: US 2024/0124321 A1
(43) Pub. Date: Apr. 18, 2024

(54) ALKALI NIOBATE FOR PIEZOELECTRIC APPLICATIONS

(71) Applicant: TANIOBIS GMBH, GOSLAR (DE)

(72) Inventors: CHRISTOPH SCHNITTER, HOLLE (DE); RALPH OTTERSTEDT, GOSLAR (DE); SVEN ALBRECHT, GOSLAR (DE)

(73) Assignee: TANIOBIS GMBH, GOSLAR (DE)

(21) Appl. No.: 18/277,386

(22) PCT Filed: Jan. 25, 2022
(86) PCT No.: PCT/EP2022/051589

§ 371 Date: Aug. 16, 2023

(30) Foreign Application Priority Data
Feb. 18, 2021 (DE) 10 2021 201 568.9

(51) Int. Cl. C01G 35/00; H10N 30/853

(52) U.S. Cl. CPC C01G 35/006; H10N 30/8542; C01P 2002/54; C01P 2002/72; C01P 2004/03; C01P 2006/12; C01P 2006/40; C01P 2006/80

(57) ABSTRACT

A niobate powder for a piezoelectric application. The niobate powder includes a general composition of Li(Na/K)NbO₃ and a carbon content per BET surface area of the niobate powder of from 10 to 100 ppm/(m²/g). The BET surface area is determined in accordance with DIN ISO 9277. The carbon content is determined via a non-dispersive infrared absorption.

### CROSS REFERENCE TO PRIOR APPLICATIONS

This application is a U.S. National Phase application under 35 U.S.C. § 371 of International Application No. PCT/EP2022/051589, filed on Jan. 25, 2022 and which claims benefit to German Patent Application No. 10 2021 201 568.9, filed on Feb. 18, 2021. The International Application was published in German on Aug. 25, 2022 as WO 2022/175030 A1 under PCT Article 21(2).

### FIELD

The present invention relates to a niobate powder of the general composition Li(Na/K)NbO₃ for piezoelectric applications, wherein the niobate powder has, based on its BET surface area, a carbon content of from 10 to 100 ppm/(m²/g). The present invention further relates to a process for producing the niobate powder and its use for producing piezoelectric materials.

### BACKGROUND

Piezoelectricity describes the change in the electric polarization and thus the occurrence of an electric potential in solid bodies when these are elastically deformed. This effect of occurrence of the piezoelectric charge in the event of mechanical deformation is generally utilized in force, pressure, and acceleration sensors as are used, for example, in medical technology, ultrasound technology, and automobile technology. The piezo elements used in the industry are usually ceramics which are made of synthetic, inorganic, ferroelectric, and polycrystalline ceramic materials. Typical base materials are modified lead zirconate titanates (PZT) and lead magnesium niobates (PMN).

As a result of changes in legal requirements, in particular the coming into force of the RoHS (Restriction of the use of Hazardous Substances) Directive, the legally permitted content of heavy metals in electric and electronic components within the European Union has been greatly restricted. There is therefore a need for alternative materials. Alkali metal niobates which have piezoelectric properties resembling those of lead-containing compounds, in particular niobates having the general compositions {Li(Na/K)}TaᵤNb₁₋ᵤO₃, abbreviated as LNKTN for u>0 and LNKN for u=0, have been identified as promising lead-free replacement for customary ceramics.

These alternatives have the disadvantage, however, that they sometimes tend to decompose at high atmospheric humidity and in the presence of water, which leads to the formation of electrically conductive compounds, as a result of which the ceramics become unsuitable for piezoelectric applications. Many efforts have for this reason already been made in the prior art to improve the resistance of such compounds to water.

US 2014/0339458 describes, for example, a piezoelectric ceramic whose main constituent is potassium sodium niobate and which, after sintering, has a carbon content of from 55 to 1240 ppm, with the ceramic displaying a particularly good flexural strength. According to the examples of US 2014/0339458, the ceramic is produced by wet milling of alkali metal carbonates or alkaline earth metal carbonates with Nb₂O₅, Ta₂O₅ and ZrO₂ and subsequent calcination. The powder thereby obtained is admixed with a PVA binder solution and additionally from 0.1 to 1.5% of carbon powder, pressed, and thermally treated at from 300 to 700° C. and, in a subsequent step, sintered at from 1000 to 1250° C. The addition of carbon here has an adverse effect on the sintered density.

JP 5588771 describes a material of the composition LiₓK_{y}Na_{(1-x-y)}NbₐTa_{b}Sb_{(1-a-b)}O₃, where x+y<1; 0≤x≤0.3; 0.1≤y≤0.7; 0.3≤a≤0.9 and 0≤b≤0.2. The material is coated with a glass to increase moisture resistance.

U.S. Pat. No. 10,193,054 describes a piezoceramic comprising, as main component, an alkali metal niobate having from 0.005 to 0.1 mol.-% of Sn on the A lattice sites and from 0.005 to 0.1 mol.-% of Zr on the B lattice sites. The occupation of the A lattice sites by Sn²⁺ ions is concluded from EXAFS images and, according to U.S. Pat. No. 10,193,054, this improves the resistance of the ceramic to atmospheric moisture.

JP 2008/160045 describes a piezoelectric powder having a hydrophobic, organic coating which is stated to reduce the sensitivity to moisture.

The alternatives proposed in the prior art have the disadvantage that the efforts to effect stabilization sometimes lead to very complicated production methods, and that some of the materials obtained are very sensitive to oxidation or else it is necessary to introduce foreign elements in order to achieve the stabilization desired.

### SUMMARY

An aspect of the present invention is to provide a niobate powder for producing lead-free piezo materials which overcomes the disadvantages of the prior art and which can be obtained by processes which can be industrially implemented.

In an embodiment, the present invention a niobate powder for a piezoelectric application. The niobate powder has a general composition of Li(Na/K)NbO₃ and a carbon content per BET surface area of the niobate powder of from 10 to 100 ppm/(m²/g). The BET surface area is determined in accordance with DIN ISO 9277. The carbon content is determined via a non-dispersive infrared absorption.

### BRIEF DESCRIPTION OF THE DRAWINGS

The present invention is described in greater detail below on the basis of embodiments and of the drawings in which:

FIG. 1 shows a graph of the measured conductivities, based on the BET surface area of the powder, of a powder suspension (2 g of powder in 100 ml of water at 20° C.) as a function of the carbon content per BET surface area of the powder after two or 32 minutes;

FIG. 2 shows a graph of the OH concentration, based on the BET surface area of the powder, determined after 2 or 32 minutes of a powder suspension (2 g of powder in 100 ml of water at 20° C.), based on the corresponding pH, as a function of the carbon content per BET surface area of the powder;

FIG. 3 shows a scanning electron micrograph of the niobate powder according to the present invention of Example 8;

FIG. 4 shows a scanning electron micrograph of the niobate powder according to Comparative Example 6; and

FIG. 5 shows an XRD spectrum of the niobate powder according to the present invention of Example 8 where the proportion of secondary phases (percentage intensity ratio of the absolute values of the highest peak of the secondary phase to the highest peak of the main phase) is 4.96%.

### DETAILED DESCRIPTION

The present invention firstly provides a niobate powder of the general composition Li(Na/K)NbO₃ for piezoelectric applications, wherein the niobate powder has, based on its BET surface area, a carbon content of from 10 to 100 ppm/(m²/g), where the BET surface area has been determined in accordance with DIN ISO 9277, the carbon content has been determined by non-dispersive infrared absorption, and the ppm are by mass.

The niobate powder according to the present invention displays a significantly decreased reactivity in respect of water and moisture compared to LNKN or LNKTN powders known hitherto. Due to their improved stability, the niobate powders according to the present invention can be processed further to form piezoelectric materials even in the presence of humid ambient air and in water-based processes, while niobate powders of this type which have been known hitherto can only be processed under low-moisture conditions using organic solvents, which is generally associated with high costs, for example, for plants which are protected from explosion(s).

For the purposes of the present invention, the BET surface area is the mass-based specific surface area determined by gas adsorption on the basis of the BET model, the fundamentals of which were described by S. Brunauer, P. H. Emmett and E. Teller in Journal of the American Chemical Society, Volume 60, No. 2, February 1938, pp. 309-319.

In an embodiment of the present invention, the niobate powder of the present invention can, for example, have the following composition:

{Liₓ(Na_{1-y}K_{y})₁₋ₓ}Nb₁₋ᵤTaᵤO₃

where 0.02<x<0.12, 0.4<y<0.6, −0.05<z<0.05, and 0≤u≤0.25.

Here, x indicates the proportion of lithium in the range 0.02<x<0.12, for example, 0.04≤x≤0.08. In the context of the present invention, it has been found that such a setting of the lithium content made it possible to achieve a higher dielectric constant, which in turn has a positive effect on the piezoelectric properties of materials later produced.

The content of sodium and potassium in the composition is indicated by 1-y or y, where 0.4<y<0.6, for example, 0.43≤y≤0.53.

The niobate powder of the present invention can, for example, have the perovskite crystal structure of the general formula ABO₃. Here, z in the composition A_{1+z}BO₃ indicates the deviation of the stoichiometry of the elements on the A lattice sites, for example, potassium, sodium and lithium, to the elements on the B lattice sites, for example, niobium and tantalum. According to the present invention, z can, for example, be −0.05<z<0.05, for example, 0<z<0.05.

In the composition of the niobate powder according to the present invention, u indicates the proportion of tantalum and can, for example, be 0≤u≤0.25. For particular applications, it can be desirable for a proportion of the B lattice sites in the crystal lattice of the niobate powder to be occupied by tantalum.

Without wishing to be tied to a particular theory, it is assumed that the carbon in the niobate powder according to the present invention is concentrated on the surface of the niobate powder and is there present in the form of niobium oxide carbonate bound to the surface of the niobate particles and not, as in the case of conventional niobate powders, in the form of alkali metal carbonates. It is assumed that the niobium oxide carbonate layer protects the niobate powder of the present invention from decomposition by action of water.

In an embodiment of the present invention, the carbon content of the niobate powder of the present invention can, for example, based on its BET surface area, be from 30 to 90 ppm/(m²/g), for example, from 40 to 90 ppm/(m²/g), in each case based on the BET surface area of the powder, where the BET surface area and the carbon content have been determined as indicated above.

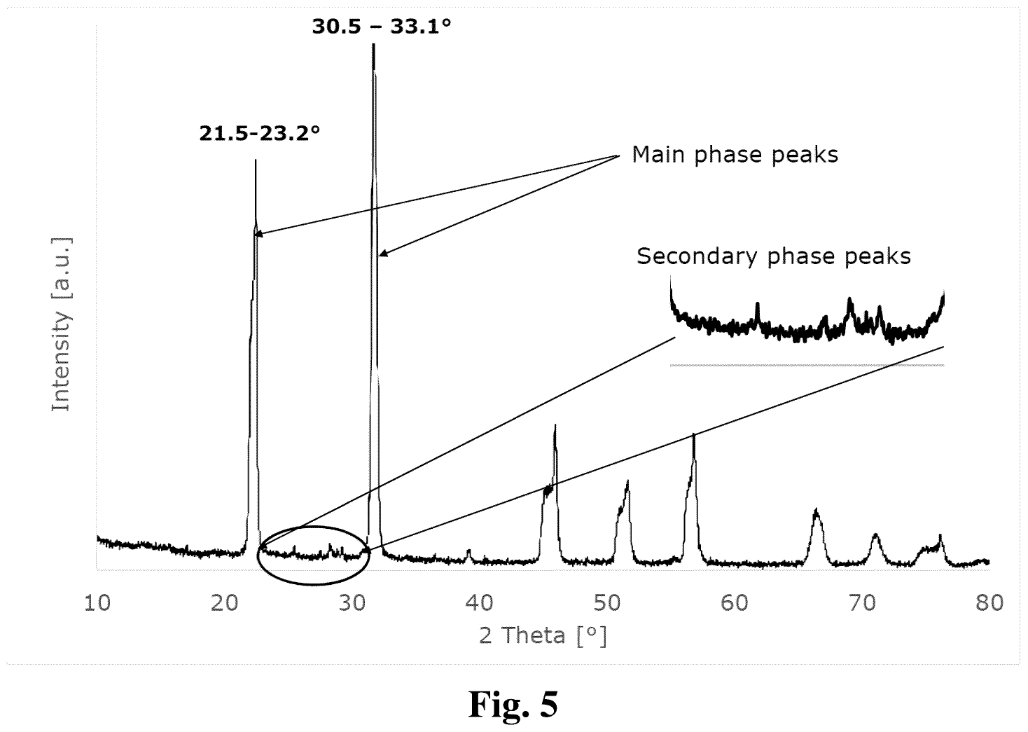

The niobate powder of the present invention can, for example, have a perovskite-like crystal structure. This is evidenced by X-ray diffraction patterns of the niobate powder of the present invention where the two peaks having the greatest intensity, referred to as main phase peaks, can, for example, be in the range from 21.5 to 23.2° 2θ and from 30.5 to 33.1° 2θ. See FIG. 5. In addition to the perovskite-like main crystal phase, the niobate powder of the present invention can comprise further crystal phases as secondary phases. These can, for example, be tungsten bronze-like crystal structures whose peaks having the highest intensity are located between the two abovementioned main phase peaks. In an embodiment of the present invention, the proportion of secondary phases in the niobate powder according to the present invention, expressed as percentage intensity ratio of the absolute values of the respective highest peak of the secondary phase between the two abovementioned main phase peaks to the respective highest main phase peak in the X-ray diffraction pattern, can, for example, be not more than 8.5%, for example, not more than 6.5%, for example, not more than 4.5%.

The niobate powder of the present invention is in particular characterized by its carbon content based on its BET surface area. In an embodiment of the present invention, the niobate powder has a BET surface area of from 2 to 8 m²/g, determined in accordance with DIN ISO 9277.

The niobate powder of the present invention is in particular intended as a replacement for conventional lead-containing piezoceramics. In order to allow unrestricted use even after the new EU regulations come into force, the niobate powder of the present invention is appropriately lead-free. The content of lead in the niobate powder of the present invention can, for example, be less than 0.01% by weight, for example, less than 0.001% by weight, in each case based on the total weight of the niobate powder.

Studies in the context of the present invention have shown that the niobate powder according to the present invention has a better stability in the presence of water than comparable niobate powders of the prior art.

Without wishing to be tied to a particular theory, it is assumed that the surface of the niobate powder is covered by a niobium oxide carbonate layer which protects the underlying alkali metal niobate powder against decomposition by water.

It is usually presumed that the partial decomposition of any alkali metal niobate powder suspended in water occurs at the particle surface according to the following reaction equation:

ANbO₃+x H₂O→A₁₋ₓHₓNbO₃+x A⁺OH⁻ where A=Li, Na, K

Due to the ions formed, both the conductivity and the OH concentration and thus the pH of the suspension increase as decomposition of the niobate powder progresses. The conductivity and the pH of a given alkali metal niobate powder suspension, in each case based on the BET surface area of the niobate powder, can accordingly be employed as a measure of the stability of the niobate powder. The slower the increase in the conductivity and/or the pH, the more stable is the niobate powder. For this reason, an embodiment of the niobate powder of the present invention can, for example, have a stability, expressed as conductivity of a suspension of the niobate powder (2 g of niobate powder in 100 ml of water, 25° C., 2 minutes reaction time) based on its BET surface area, of from 10 to 90 (μS/cm)/(m²/g), for example, from 10 to 70 (μS/cm)/(m²/g), for example, from 10 to 40 (μS/cm)/(m²/g). The BET surface area of the niobate powder was here determined in accordance with DIN ISO 9277, while the conductivity was determined by the conductivity of the suspension of the niobate powder being measured after reaction with water for 2 minutes (2 g of niobate powder per 100 ml of water) at 25° C.

It has furthermore surprisingly been found that the increase in the conductivity of an aqueous suspension of the niobate powder of the present invention occurs significantly more slowly than expected, which is considered to be a further indication of the surprising stability of the powder. For this reason, an embodiment of the niobate powder of the present invention provides that the niobate powder can, for example, have a stability, expressed as conductivity of a suspension of the niobate powder (2 g of niobate powder per 100 ml of water, 25° C., 32 minutes reaction time) based on its BET surface area, of from 10 to 100 (μS/cm)/(m²/g), for example, from 10 to 80 (μS/cm)/(m²/g), for example, from 10 to 50 (μS/cm)/(m²/g). The BET surface area of the niobate powder was here determined in accordance with DIN ISO 9277, while the conductivity was determined by measuring the conductivity of the suspension after reaction with water for 32 minutes (2 g of niobate powder per 100 ml of water) at 25° C.

In an embodiment of the present invention, the conductivity of an aqueous suspension (2 g of niobate powder per 100 ml of water) of the niobate powder of the present invention at 25° C. increases, for example, by not more than 10 (μS/cm)(m²/g) during a reaction time of 30 minutes.

As further measure of the stability of the niobate powder of the present invention, it is possible to employ, according to the above considerations, the pH and, coupled thereto, the concentration of OH ions (OH concentration) of an aqueous suspension of the niobate powder. In an embodiment of the present invention, the niobate powder of the present invention can, for example, have a stability, expressed as the OH concentration of an aqueous suspension of the niobate powder of the present invention (2 g of niobate powder, 25° C., 2 minutes reaction time) based on its BET surface area, of from 2.0*10⁻⁵ to 8*10⁻⁵ (mol/l)/(m²/g). The BET surface area was here determined in accordance with DIN ISO 9277, while the OH concentration was determined from a measurement of the pH of the suspension (2 g of niobate powder in 100 ml of water) at 25° C. after reaction for 2 minutes. Studies have shown that the OH concentration increases surprisingly little after a longer reaction time. In an embodiment of the present invention, the niobate powder of the present invention can, for example, have a stability expressed as the OH concentration of an aqueous suspension of the niobate powder of the present invention (2 g of niobate powder, 25° C., 32 minutes reaction time) based on its BET surface area of from 2.0*10⁻⁵ to 9*10⁻⁵ (mol/l)/(m²/g), where the BET surface area was here determined in accordance with DIN ISO 9277, while the OH concentration was determined from a measurement of the pH of the suspension (2 g of niobate powder in 100 ml of water) at 25° C. after reaction for 32 minutes.

The niobate powder of the present invention can, for example, have a particle size D50 of from 0.3 to 1.5 μm, for example, from 0.5 to 1.0 μm, determined by laser light scattering after pretreatment with ultrasound for 5 minutes, in accordance with ASTM B822.

It has surprisingly been found in the context of the present invention that the advantageous properties of the niobate powder of the present invention are in particular obtained when the production of the niobate powder is carried out in a CO₂-free atmosphere. In an embodiment, the niobate powder of the present invention can, for example, be obtained by a process comprising the following steps:
i) Provision of an aqueous solution of salts of lithium, sodium and potassium, where the salts are selected from the group of oxides, hydroxides, peroxides, superoxides, nitrates and nitrites of the elements lithium, sodium and potassium and mixtures thereof, where the solution is produced with exclusion of CO₂;
ii) Provision of an aqueous suspension of a second starting material, where the second starting material is selected from the group of the oxides and oxide hydrates of niobium, wherein the suspension is produced with exclusion of CO₂;
iii) Mixing of the aqueous solution from step i) and the suspension from step ii) with exclusion of CO₂ to give a mixed suspension;
iv) Drying with exclusion of CO₂ of the mixed suspension obtained under iii) to give a granular material;
v) Calcination with exclusion of CO₂ of the granular material obtained under iv); and
vi) Conditioning of the surface of the calcined granular material in the presence of CO₂.

In an embodiment of the present invention, the second starting material can, for example, additionally contain oxides and/or oxide hydrates of tantalum.

Alkali metal niobate powders for utilization in lead-free piezoceramics are usually produced from carbon-containing precursors such as alkali metal carbonates. Most process steps are carried out in ambient air so that CO₂ present in the ambient air can have unhindered access. The niobate powders obtained in this way not only have high proportions of carbon, but also a strong tendency to be decomposed by water. It is presumed that the carbon is bound in the form of alkali metal carbonates in the material. These alkali metal carbonates are, however, hygroscopic and water-soluble, and therefore promote the decomposition of the alkali metal niobate powder and thus have an adverse effect on the piezoelectric properties. In contrast thereto, it is assumed that production in a CO₂-free atmosphere, at least in an atmosphere low in CO₂, and controlled conditioning in the presence of CO₂ leads to the carbon being present in the form of niobium oxide carbonate on the surface of the niobate particles, as a result of which the surprising stability of the niobate powder according to the present invention which is observed is achieved.

In the context of the present invention, it has surprisingly been found that a process for producing niobate powders in which the niobate powders are firstly produced in a carbon-free or at least a low-carbon form and are exposed to a CO₂-containing gas stream under defined conditions in a subsequent process step yields niobate powders according to the present invention which have a surprisingly high resistance to water and moisture. For this reason, the present invention further provides a process for producing the niobate powder of the present invention, which comprises the following steps:
i) Provision of an aqueous solution of salts of lithium, sodium and potassium, where the salts are selected from the group of the oxides, hydroxides, peroxides, superoxides, nitrates and nitrites of the elements lithium, sodium and potassium and mixtures thereof, where the solution is produced with exclusion of CO₂;
ii) Provision of an aqueous suspension of a second starting material, where the second starting material is selected from the group of the oxides and oxide hydrates of niobium, where the suspension is produced with exclusion of CO₂;
iii) Mixing of the aqueous solution from step i) and the suspension from step ii) with exclusion of CO₂ to give a mixed suspension;
iv) Drying with exclusion of CO₂ of the mixed suspension obtained in step iii) to give a granular material;
v) Calcination with exclusion of CO₂ of the granular material obtained in step iv); and
vi) Conditioning of the surface of the calcined granular material in the presence of CO₂.

For the production of the niobate powders of the present invention, it has been found to be particularly advantageous for the process steps i) to v) to be carried out with exclusion of CO₂, for example, in a CO₂-free atmosphere. Techniques of this type are known to a person skilled in the art and are routinely used by such a person.

In an embodiment of the present invention, the second starting material can, for example, additionally contain oxides and/or oxide hydrates of tantalum.

The production of the niobate powder of the present invention is carried out under controlled conditions. In an embodiment, the conditioning of the calcined granular material can, for example, be carried out via a stream of air admixed with CO₂, with the proportion of added CO₂ in the air stream, for example, being from 1 to 30% by volume, for example, from 5 to 20% by volume, in each case based on the total volume of the air stream. The conditioning can also advantageously be carried out in a calcination furnace so that a complicated transfer of the calcined granular material can be dispensed with. In an embodiment of the process of the present invention, the conditioning in step vi) can, for example, be carried out in a calcination furnace. Successful conditioning can also be influenced by the relative atmosphere humidity of the surroundings. It has been found to be advantageous for the relative humidity of the air/CO₂ mixture used for conditioning to be kept within a particular range. In an embodiment of the present invention, the conditioning can, for example, be carried out in an atmosphere having a relative atmospheric humidity before introduction of the CO₂ of from 40 to 60%, determined at 20° C. A relatively narrow temperature window of less than 500° C. has also been found to be advantageous for carrying out the conditioning. The conditioning in step vi) of the process of the present invention can therefore, for example, be carried out at a temperature of from 200 to 400° C., for example, from 250 to 300° C. As has surprisingly been found, the formation of undesirable hydrogencarbonates increases at temperatures below 200° C., while a controlled production is made difficult at temperatures above the values indicated because of the increasing reactivity of the alkali metal niobate powder.

It has been found to be advantageous in the process of the present invention for the starting materials to have a very small particle size. In an embodiment of the process of the present invention, the second starting material can therefore, for example, have a maximum primary particle size of less than 1.0 μm, for example, less than 0.5 μm, for example, less than 0.3 μm, determined by image analysis of scanning electron micrographs.

Contrary to general expectations, only a minimal tendency of the powder particles to agglomerate has been observed in the process of the present invention. The solids in the mixed suspension in step iii) therefore have, in an embodiment of the process of the present invention, a particle size D50 of less than 2.0 μm, for example, of less than 1.5 μm, for example, of less than 1.2 μm, determined by laser light scattering without pretreatment in an ultrasonic bath, in accordance with ASTM B822. The D50 value of the particle size distribution denotes the proportion of particles which have a particle size above or below the value indicated.

In the production of the niobate powders of the present invention, it has been found to be particularly advantageous to carry out the drying in step iv) of the process with exclusion of CO₂. The drying can, for example, be carried out via a static drying, a spray drying, a freeze drying or a spray calcination.

It has surprisingly been found that the calcination of the granular material can be carried out at significantly lower temperatures than are customary in the prior art. It has thus been found to be advantageous to carry out the calcination in step v) of the process of the present invention at temperatures in the range from 500 to 1000° C. In an embodiment of the present invention, the calcination in step v) of the process of the present invention can, for example, be carried out at a temperature of from 500 to 1000° C.; for example, from 650 to 800° C., for example, for a time of from 0.5 to 2 hours.

In order to be able to carry out targeted conditioning of the granular material obtained after calcination, this material can, for example, be cooled after calcination. In an embodiment of the present invention, the calcination can, for example, be followed by a cooling step, for example, with temperatures of from 200 to 400° C., for example, from 250 to 300° C., in the granular material being attained.

The niobate powders of the present invention are particularly suitable for the production of piezoelectric materials because of their surprising stability. For this reason, the present invention further provides for the use of the niobate powder of the present invention for producing piezoelectric materials. The materials can, for example, be ceramic materials, composites, and composite materials.

The present invention further provides a piezoelectric material, for example, a piezoelectric ceramic or a piezoelectric composite, produced from the niobate powder of the present invention. The ceramics according to the present invention are usually produced by bringing the niobate powder of the present invention to the size and shape desired for the function by a green shaping technique, for example, pressing, (screen) printing or film drawing, with the aid of binders, solvents, rheological additives and optionally sintering aids, and subsequently sintering the green bodies to produce a ceramic, i.e., to form a microcrystalline assembly of crystal grains. In the case of multilayer actuators, unsintered sheets of niobate powder and binder are alternately printed with metal paste, stacked, cut and then sintered together. The sintered ceramic can, after metallization of exterior surfaces, subsequently be poled in high electric fields in order to obtain piezoelectric properties.

The piezoelectric material can, for example, be employed for producing piezoelectric elements such as multilayer actuators, bending transducers, ultrasonic sensors, and ultrasonic transducers, as are used in medical technology, ultrasound technology, and automobile technology.

The present invention will be illustrated with the aid of the following examples, however, these examples should not be construed in any way as restricting the inventive concept.

### EXAMPLES

Various niobate powders of the composition (Li_{0.07}(Na_{0.50}K_{0.50})_{0.93})_{1.02}NbO₃ (Examples 1 to 6 and 8 to 10) and of the composition (Li_{0.07}(Na_{0.50}K_{0.50})_{0.93})_{1.02}Nb_{0.80}Ta_{0.20}O₃ (Example 7) were produced by the process described below, with the work being carried out with exclusion of CO₂ unless indicated otherwise. In the case of Example 1, a mixture of an aqueous solution containing 21.62 g of lithium nitrate (LiNO₃), 177.02 g of sodium nitrate (NaNO₃) and 210.59 g of potassium nitrate (KNO₃) and an aqueous suspension of 1562 g of niobium hydroxide (Nb(OH)₅) containing 26.12% by weight of Nb, was firstly produced. The same molar ratios as for Example 1 were employed for Examples 2 to 6 and 8 to 10. For Example 7, 20 mol.-% of the niobium hydroxide was replaced by tantalum hydroxide. The mixtures were each dried at 95° C. under reduced pressure and under a CO₂-free air atmosphere in a drying oven. The granular material thereby obtained was calcined at from 700 to 800° C. for 1.5 hours in a calcination furnace and then cooled to 300 or 250° C. in a stream of dried, CO₂-free air. The product thereby obtained was treated for 40 minutes at 300 or 250° C. in a stream of air to which from 5 to 15% by volume of CO₂ had been added. The relative atmospheric humidity of the air used for conditioning before introduction of the CO₂ was 45%, determined at 20° C. The respective reaction conditions are summarized in Table 1.

TABLE 1
Production Parameters of the Examples

| | | CO₂ content | |
|---|---|---|---|
| | Calcination | of the | Temperature |
| | temperature | CO₂/air mixture | of |
| | [° C.] | [% by volume] | conditioning [° C.] |
| Example 1 | 800 | 10 | 300 |
| Example 2 | 750 | 10 | 300 |
| Example 3 | 700 | 10 | 300 |
| Example 4 | 800 | 5 | 300 |
| Example 5 | 725 | 10 | 300 |
| Example 6 | 775 | 10 | 300 |
| Example 7 | 725 | 15 | 300 |
| Example 8 | 750 | 15 | 300 |
| Example 9 | 750 | 15 | 250 |
| Example 10 | 775 | 15 | 250 |

The powder of Comparative Example 1 having the composition (Li_{0.07}(Na_{0.50}K_{0.50})_{0.93})_{1.02}NbO₃ was produced in a first step by ball milling of 22.25 g of lithium carbonate (Li₂CO₃), 212.01 g of sodium carbonate (Na₂CO₃), and 276.46 g of potassium carbonate (K₂CO₃) with 1121.0 g of niobium oxide (Nb₂O₅) in ethanol for 24 hours. The same molar ratios as for Comparative Example 1 were employed for Comparative Examples 2 to 8. The mixtures thereby obtained were treated by drying in ambient air without the exclusion of CO₂, homogenization and calcination at various temperatures (see Table 2) in the range from 750 to 950° C. in ambient air without the exclusion of CO₂. In the case of these materials, CO₂ conditioning for 40 minutes at 300° C. using 5% by volume of CO₂ in air (Comparative Example 7) or 15% by volume of CO₂ in air (Comparative Example 8) and a relative atmospheric humidity of 45% at 20° C. of the air used for conditioning before addition of the CO₂ did not lead to an improvement in the stability in respect of water; the conductivity and the OH concentration of aqueous suspensions of the comparative materials did not change significantly as a result of conditioning in a CO₂-containing atmosphere.

TABLE 2
Calcination Temperatures of the Comparative Examples

| | Calcination temperature |
|---|---|
| | [° C.] |
| Comparative Example 1 | 850 |
| Comparative Example 2 | 900 |
| Comparative Example 3 | 950 |
| Comparative Example 4 | 850 |
| Comparative Example 5 | 800 |
| Comparative Example 6 | 750 |
| Comparative Example 7 | 750 |
| Comparative Example 8 | 750 |

The powders produced in this way were analyzed by chemical analysis of the main elements. The physical properties were characterized by XRD, SEM particle size distribution, and BET surface area measurement in accordance with DIN ISO 9277. The carbon content was determined by non-dispersive infrared absorption by burning the sample material after weighing into an unglazed porcelain boat in the presence of oxygen in a tube furnace. The analysis gas CO₂ was detected by non-dispersive infrared absorption. The analysis was carried out in a carbon-sulfur analyzer from Leco Instrumente GmbH. The stability of the resulting niobate powder in respect of water was secondly determined by suspending 2 g of the niobate powder in 100 ml of deionized water, stirring at 25° C. for 2 minutes or 32 minutes, and measuring the conductivity and the pH of the suspension, with the pH value determined being used as a basis for calculation of the OH concentration. The results are summarized in Table 3.

TABLE 3

| | | | | Conduc- | | | |
|---|---|---|---|---|---|---|---|
| | | | | tivity | Cond. | | Cond. |
| | | | C/BET | (Cond.) | 2 min/BET | Cond. | 32 min/BET |
| | BET | C | ppm/ | 2 min | (μS/cm)/ | 32 min | (μS/cm)/ |
| | m²/g | ppm | (m²/g) | μS/cm | (m²/g) | μS/cm | (m²/g) |
| Example 1 | 2.96 | 259 | 88 | 104 | 35.14 | 123 | 41.55 |
| Example 2 | 4.37 | 374 | 86 | 141 | 32.27 | 171 | 39.13 |
| Example 3 | 6.79 | 390 | 57 | 139 | 20.47 | 144 | 21.21 |
| Example 4 | 3.34 | 241 | 72 | 132 | 39.52 | 148 | 44.31 |
| Example 5 | 6.05 | 369 | 61 | 143 | 23.64 | 159 | 26.28 |
| Example 6 | 3.97 | 347 | 87 | 137 | 34.51 | 148 | 37.28 |
| Example 7 | 6.1 | 281 | 46 | 99 | 16.23 | 102 | 16.72 |
| Example 8 | 5.14 | 291 | 57 | 119 | 23.15 | 126 | 24.51 |
| Example 9 | 4.68 | 248 | 53 | 118 | 25.21 | 124 | 26.50 |
| Example 10 | 4.36 | 268 | 61 | 129 | 29.59 | 133 | 30.50 |
| Comparative | 2.85 | 384 | 135 | 322 | 112.98 | 362 | 127.02 |
| Example 1 | | | | | | | |
| Comparative | 1.89 | 367 | 194 | 235 | 124.34 | 287 | 151.85 |
| Example 2 | | | | | | | |
| Comparative | 1.40 | 321 | 229 | 183 | 130.71 | 189 | 135.00 |
| Example 3 | | | | | | | |
| Comparative | 2.33 | 337 | 145 | 258 | 110.73 | 351 | 150.64 |
| Example 4 | | | | | | | |
| Comparative | 3.08 | 479 | 156 | 325 | 105.52 | 397 | 128.90 |
| Example 5 | | | | | | | |
| Comparative | 3.86 | 518 | 134 | 385 | 99.74 | 436 | 112.95 |
| Example 6 | | | | | | | |
| Comparative | 3.93 | 582 | 148 | 392 | 99.75 | 441 | 112.21 |
| Example 7 | | | | | | | |
| Comparative | 3.93 | 639 | 163 | 376 | 95.67 | 398 | 101.27 |
| Example 8 | | | | | | | |

| | | | OH⁻ Conc. | | | OH⁻ Conc. |
|---|---|---|---|---|---|---|
| | | OH⁻ Conc. | 2 min/BET | | OH⁻ Conc. | 2 min/BET |
| | pH | 2 min | (mol/l)/ | pH | 32 min | (mol/l)/ |
| | 2 min | mol/l | (m²/g) | 32 min | mol/l | (m²/g) |
| Example 1 | 10.21 | 1.62E−04 | 5.48E−05 | 10.31 | 2.04E−04 | 6.90E−05 |
| Example 2 | 10.25 | 1.78E−04 | 4.07E−05 | 10.34 | 2.19E−04 | 5.01E−05 |
| Example 3 | 10.32 | 2.09E−04 | 3.08E−05 | 10.35 | 2.24E−04 | 3.30E−05 |
| Example 4 | 10.32 | 2.09E−04 | 6.26E−05 | 10.47 | 2.95E−04 | 8.84E−05 |
| Example 5 | 10.24 | 1.74E−04 | 2.87E−05 | 10.27 | 1.86E−04 | 3.08E−05 |
| Example 6 | 10.36 | 2.29E−04 | 5.77E−05 | 10.38 | 2.40E−04 | 6.04E−05 |
| Example 7 | 10.24 | 1.74E−04 | 2.85E−05 | 10.27 | 1.86E−04 | 3.05E−05 |
| Example 8 | 10.28 | 1.91E−04 | 3.71E−05 | 10.31 | 2.04E−04 | 3.97E−05 |
| Example 9 | 10.36 | 2.29E−04 | 4.90E−05 | 10.39 | 2.45E−04 | 5.25E−05 |
| Example 10 | 10.38 | 2.40E−04 | 5.50E−05 | 10.45 | 2.82E−04 | 6.46E−05 |
| Comparative | 10.47 | 2.95E−04 | 1.04E−04 | 10.51 | 3.24E−04 | 1.14E−04 |
| Example 1 | | | | | | |
| Comparative | 10.42 | 2.63E−04 | 1.39E−04 | 10.43 | 2.69E−04 | 1.42E−04 |
| Example 2 | | | | | | |
| Comparative | 10.52 | 3.31E−04 | 2.37E−04 | 10.58 | 3.80E−04 | 2.72E−04 |
| Example 3 | | | | | | |
| Comparative | 10.32 | 2.09E−04 | 8.97E−05 | 10.51 | 3.24E−04 | 1.39E−04 |
| Example 4 | | | | | | |
| Comparative | 10.56 | 3.63E−04 | 1.18E−04 | 10.63 | 4.27E−04 | 1.38E−04 |
| Example 5 | | | | | | |
| Comparative | 10.72 | 5.25E−04 | 1.36E−04 | 10.77 | 5.89E−04 | 1.53E−04 |
| Example 6 | | | | | | |
| Comparative | 10.69 | 4.90E−04 | 1.25E−04 | 10.79 | 6.17E−04 | 1.57E−04 |
| Example 7 | | | | | | |
| Comparative | 10.92 | 8.32E−04 | 2.12E−04 | 10.94 | 8.71E−04 | 2.22E−04 |
| Example 8 | | | | | | |

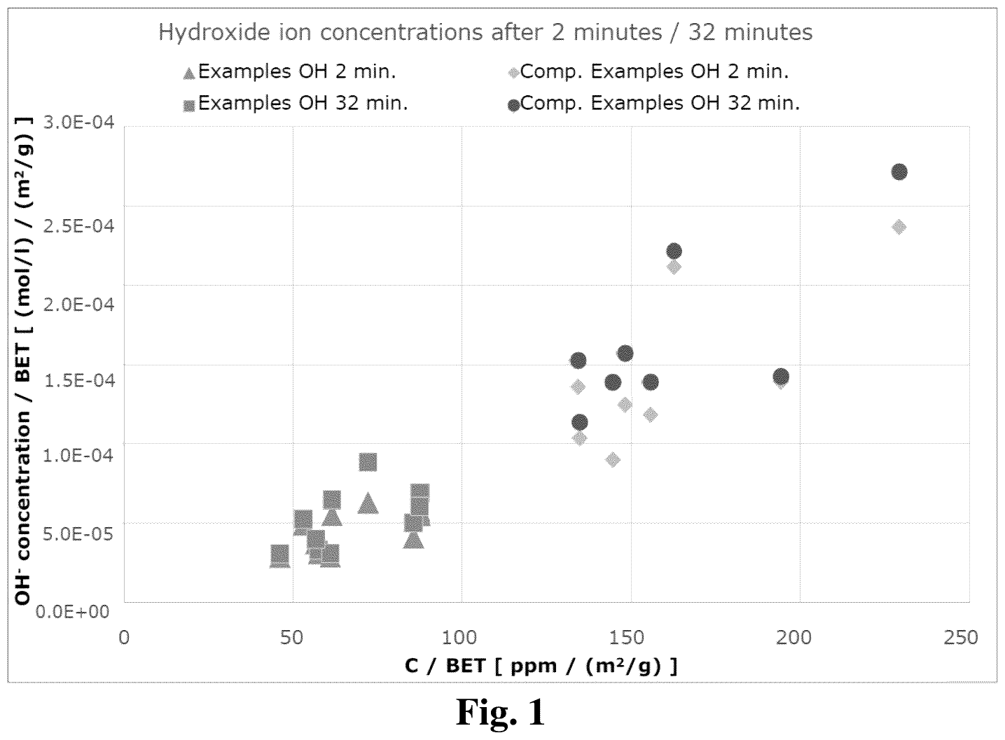

FIG. 1 shows a graph of the measured conductivities, based on the BET surface area of the powder, of a powder suspension (2 g of powder in 100 ml of water at 20° C.) as a function of the carbon content per BET surface area of the powder after two or 32 minutes.

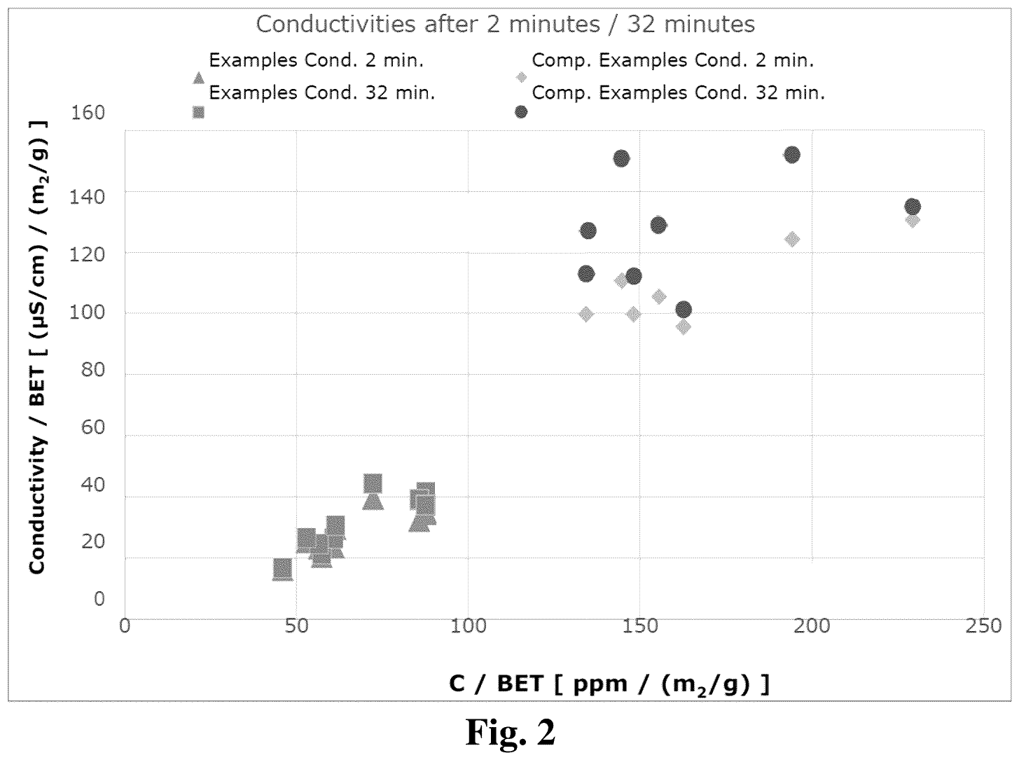

FIG. 2 shows a graph of the OH concentration, based on the BET surface area of the powder, determined after 2 or 32 minutes of a powder suspension (2 g of powder in 100 ml of water at 20° C.), based on the corresponding pH, as a function of the carbon content per BET surface area of the powder.

As can be seen from FIGS. 1 and 2, powders having a carbon content based on their BET surface area which is in the range according to the present invention display a significantly improved stability in respect of water, expressed as conductivity and OH concentration of the suspension, than comparable powders produced by conventional processes.

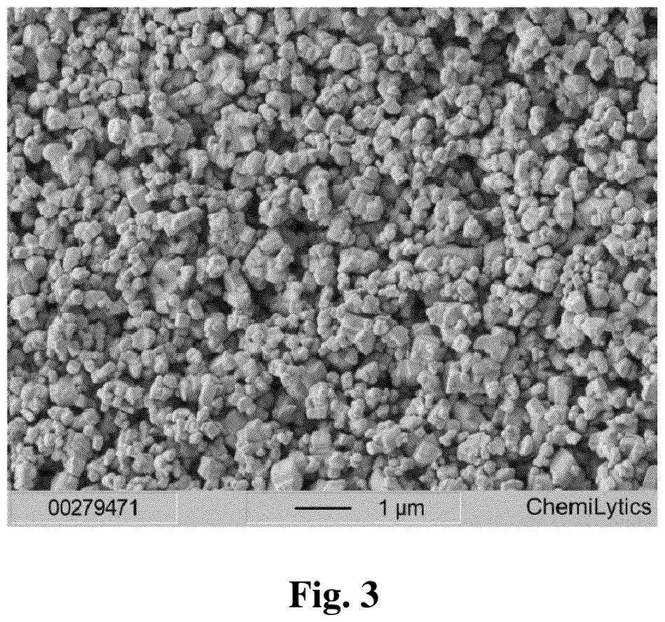

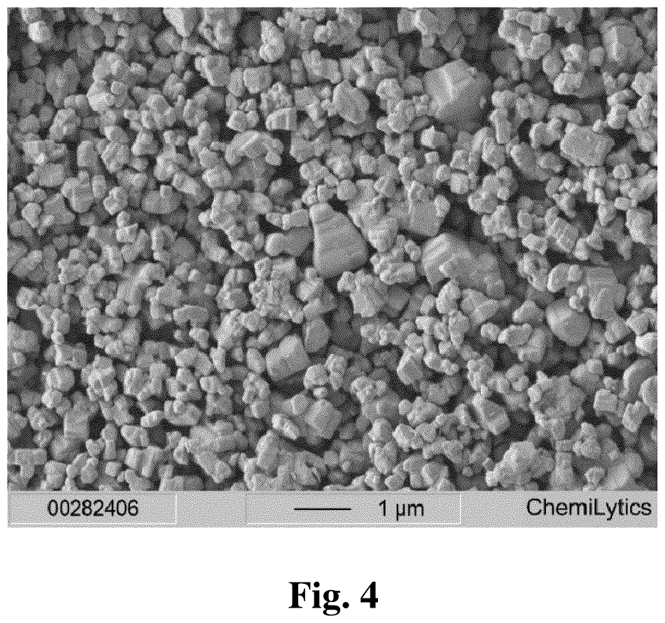

FIGS. 3 and 4 show in each case a scanning electron micrograph of the niobate powder according to the present invention of Example 8 (FIG. 3) or of the niobate powder of Comparative Example 6 (FIG. 4). Comparison of the two images clearly shows the differences in the surface morphology of the powders, which are attributed to the controlled conditioning of the powder according to the present invention.

FIG. 5 shows an XRD spectrum of the niobate powder according to the present invention of Example 8, where the proportion of secondary phases (percentage intensity ratio of the absolute values of the highest peak of the secondary phase to the highest peak of the main phase) is 4.96%.

As the examples show, the process of the present invention makes it possible to produce, under mild conditions, fine but predominantly crystallized and only weakly agglomerated alkali metal niobate powders which have a high homogeneity and a reactivity with water which can be decreased by a treatment with CO₂. A very sinter-active, fine alkali metal niobate powder which has a controlled carbon content and which has a significantly reduced reactivity in respect of water and (atmospheric) moisture and thus better storage stability, more stable processability by pressing and sintering, and which offers the possibility of aqueous formulation in the production of casting slips for producing multilayer actuators is thereby obtained. The niobate powders of the present invention also display very small primary particle sizes and a significantly narrower distribution of the primary particle size than powders known hitherto.

The present invention is not limited to embodiments described herein; reference should be had to the appended claims.

What is claimed is:

1-15. (canceled)

16. A niobate powder for a piezoelectric application, the niobate powder comprising:
a general composition of Li(Na/K)NbO₃; and
a carbon content per BET surface area of the niobate powder of from 10 to 100 ppm/(m²/g),
wherein,
the BET surface area is determined in accordance with DIN ISO 9277, and
the carbon content is determined via a non-dispersive infrared absorption.

17. The niobate powder as recited in claim 16, wherein the niobate powder further comprises a composition of,
{Liₓ(Na_{1-y}K_{y})₁₋ₓ}_{1+z}Nb₁₋ᵤTaᵤO₃,
wherein,
0.02<x<0.12,
0.4<y<0.6,
−0.05<z<0.05, and
0≤u≤0.25.

18. The niobate powder as recited in claim 16, wherein the niobate powder comprises a BET surface area of from 2 to 8 m²/g as determined in accordance with DIN ISO 9277.

19. The niobate powder as recited in claim 16, wherein, the niobate powder is either lead free or further comprises a lead content of less than 0.01 wt.-%, based in each case on a total weight of the niobate powder.

20. The niobate powder as recited in claim 16, wherein,
the niobate powder further comprises a stability of from 10 to 90 (μS/cm)/(m²/g),
the stability is expressed as a conductivity of a suspension of the niobate powder per BET surface area of the niobate powder,
the BET surface area is determined in accordance with DIN ISO 9277, and
the conductivity is determined by measuring the conductivity of the suspension after 2 g of the niobate powder is reacted with 100 ml of water for 2 minutes.

21. The niobate powder as recited in claim 20, wherein the stability of the niobate powder is from 10 to 40 (μS/cm)/(m²/g).

22. The niobate powder as recited in claim 16, wherein,
the niobate powder further comprises a stability of from 10 to 100 (μS/cm)/(m²/g),
the stability is expressed as a conductivity of a suspension of the niobate powder per BET surface area of the niobate powder,
the BET surface area is determined in accordance with DIN ISO 9277, and
the conductivity is determined by measuring the conductivity of the suspension after 2 g of the niobate powder is reacted with 100 ml of water for 32 minutes.

23. The niobate powder as recited in claim 22, wherein the stability of the niobate powder is from 10 to 50 (μS/cm)/(m²/g).

24. The niobate powder claim as recited in claim 22, wherein the conductivity of the suspension of the niobate powder does not increase by more than 10 (μS/cm)/(m²/g) in 30 minutes.

25. The niobate powder as recited in claim 16, wherein,
the niobate powder further comprises a stability of from 2.0*10⁻⁵ to 8*10⁻⁵ (mol/l)/(m²/g),
the stability is expressed as an OH concentration of a suspension of the niobate powder per BET surface area of the niobate powder,
the BET surface area is determined in accordance with DIN ISO 9277, and
the OH concentration is determined from a measurement of a pH of the suspension after 2 g of niobate powder is reacted with 100 ml of water at 25° C. for 2 minutes.

26. The niobate powder as recited in claim 16, wherein the niobate powder is produced by a process comprising:
providing an aqueous solution of salts of lithium, salts of sodium, and salts of potassium, wherein each of the salts of lithium, the salts of sodium, and the salts of potassium are selected from the group of oxides, hydroxides, peroxides, superoxides, nitrates and nitrites of the elements lithium, sodium and potassium and mixtures thereof, the aqueous solution being produced with an exclusion of CO₂;
providing of an aqueous suspension which is selected from the group of oxides and oxide hydrates of niobium, the aqueous suspension being produced with an exclusion of CO₂;
mixing of the aqueous solution and the aqueous suspension with an exclusion of CO₂ so as to provide a mixed suspension;
drying the mixed suspension with an exclusion of CO₂ so as to provide a granular material;
calcining the granular material with an exclusion of CO₂ so as to provide a calcined granular material; and
conditioning a surface of the calcined granular material in the presence of CO₂.

27. A process for producing the niobate powder as recited in claim 16, the process comprising:
providing an aqueous solution of salts of lithium, salts of sodium, and salts of potassium, wherein each of the salts of lithium, the salts of sodium, and the salts of potassium are selected from the group of oxides, hydroxides, peroxides, superoxides, nitrates and nitrites of the elements lithium, sodium and potassium and mixtures thereof, the aqueous solution being produced with an exclusion of CO₂;
providing of an aqueous suspension which is selected from the group of oxides and oxide hydrates of niobium, the aqueous suspension being produced with an exclusion of CO₂;
mixing of the aqueous solution and the aqueous suspension with an exclusion of CO₂ so as to provide a mixed suspension;
drying the mixed suspension with an exclusion of CO₂ so as to provide a granular material;
calcining the granular material with an exclusion of CO₂ so as to provide a calcined granular material; and
conditioning a surface of the calcined granular material in the presence of CO₂.

28. The process as recited in claim 27, wherein,
the conditioning of the surface of the calcined granular material is performed via a stream of air which is admixed with CO₂, and
a proportion of the CO₂ which is admixed into the stream of air is from 1 to 30% by volume based on a total volume of the stream of air.

29. The process as recited in claim 28, wherein the proportion of the CO₂ which is admixed into the stream of air is from 5 to 20% by volume based on the total volume of the stream of air.

30. The process as recited in claim 27, wherein the calcining of the granular material with the exclusion of CO₂ so as to provide the calcined granular material is performed at a temperature of from 500 to 1000° C.

31. The process as recited in claim 27, wherein the calcining of the granular material with the exclusion of CO₂ so as to provide the calcined granular material is performed at a temperature of from 650 to 800° C. for a time of from 0.5 to 2 hours.

32. A method of using the niobate powder as recited in claim 16 for producing a piezoelectric ceramic, the method comprising:
providing the niobate powder as recited in claim 16; and
using the niobate powder to produce the piezoelectric ceramic.

33. A piezoelectric material which is produced from the niobate powder as recited in claim 16.

34. The piezoelectric material as recited in claim 33, wherein the material is a ceramic material or a composite material.
